(19) United States
(12) Patent Application Publication
(10) Pub. No.: US 2010/0241923 A1
(43) Pub. Date: Sep. 23, 2010

(54) Communication device employing LDPC (Low Density Parity Check) coding with Reed-Solomon (RS) and/or binary product coding

(75) Inventors: Zhongfeng Wang, Irvine, CA (US); Ba-Zhong Shen, Irvine, CA (US); Kang Xiao, Irvine, CA (US); James R. Fife, Corona Del Mar, CA (US); Sudeep Bhoja, San Jose, CA (US)

Correspondence Address: GARLICK HARRISON & MARKISON, P.O. BOX 160727, AUSTIN, TX, 78716-0727, US

(73) Assignee: BROADCOM CORPORATION, IRVINE, CA (US)

(21) Appl. No.: 12/726,219

(22) Filed: Mar. 17, 2010

Related U.S. Application Data
(60) Provisional application No. 61/161,030, filed on Mar. 17, 2009.
(60) Provisional application No. 61/170,591, filed on Apr. 17, 2009.

(51) Int. Cl. H03M 13/29; G06F 11/10; H03M 13/15; H03M 13/07

(52) U.S. Cl. 714/755; 714/782; 714/784; 714/758; 714/E11.032

(57) ABSTRACT

Communication device employing LDPC (Low Density Parity Check) coding with Reed-Solomon (RS) and/or binary product coding. An LDPC code is concatenated with a RS code or a binary product code (e.g., using row and column encoding of matrix formatted bits) thereby generating coded bits for use in generating a signal that is suitable to be launched into a communication channel. Various ECCs/FECs may be employed including a BCH (Bose and Ray-Chaudhuri, and Hocquenghem) code, a Reed-Solomon (RS) code, an LDPC (Low Density Parity Check) code, etc. and various implementations of cyclic redundancy check (CRC) may accompany the product coding and/or additional ECC/FEC employed. The redundancy of such coded signals as generated using the principles herein are in the range of approximately 20% thereby providing a significant amount of redundancy and a high coding gain. Soft decision decoding may be performed on such coded signal generated herein.

### CROSS REFERENCE TO RELATED PATENTS/PATENT APPLICATIONS

### Provisional Priority Claims

The present U.S. Utility Patent Application claims priority pursuant to 35 U.S.C. §119(e) to the following U.S. Provisional Patent Applications which are hereby incorporated herein by reference in their entirety and made part of the present U.S. Utility Patent Application for all purposes:

1. U.S. Provisional Application Ser. No. 61/161,030, entitled “Forward error correction (FEC) scheme for communications,” (Attorney Docket No. BP20232), filed Mar. 17, 2009, pending.

2. U.S. Provisional Application Ser. No. 61/170,591, entitled “Communication device employing LDPC (Low Density Parity Check) and/or Reed-Solomon (RS) coding with binary product coding,” (Attorney Docket No. BP20521), filed Apr. 17, 2009, pending.

### INCORPORATION BY REFERENCE

The following U.S. Utility Patent Application is hereby incorporated herein by reference in its entirety and is made part of the present U.S. Utility Patent Application for all purposes:

1. U.S. Utility application Ser. No. 12/725,887, entitled “Forward error correction (FEC) scheme for communications,” (Attorney Docket No. BP20232), filed concurrently on Mar. 17, 2010, pending, which claims priority pursuant to 35 U.S.C. §119(e) to the following U.S. Provisional Patent Application which is hereby incorporated herein by reference in its entirety and made part of the present U.S. Utility Patent Application for all purposes:
a. U.S. Provisional Application Ser. No. 61/161,030, entitled “Forward error correction (FEC) scheme for communications,” (Attorney Docket No. BP20232), filed Mar. 17, 2009, pending.

### BACKGROUND OF THE INVENTION

1. Technical Field of the Invention

The invention relates generally to communication devices; and, more particularly, it relates to communication devices that employ LDPC (Low Density Parity Check) and/or Reed-Solomon (RS) coding with binary product coding.

2. Description of Related Art

Data communication systems have been under continual development for many years. One such type of communication system that has been of significant interest lately is a communication system that employs iterative error correction codes (ECCs) that operate in accordance with forward error correction (FEC). There are a variety of types of ECCs including Reed-Solomon (RS) code, turbo codes, turbo trellis code modulation (TTCM) code, LDPC (Low Density Parity Check) code, etc. Communications systems with iterative codes are often able to achieve lower bit error rates (BER) than alternative codes for a given signal to noise ratio (SNR).

A continual and primary directive in this area of development has been to try continually to lower the SNR required to achieve a given BER within a communication system. The ideal goal has been to try to reach Shannon's limit in a communication channel. Shannon's limit may be viewed as being the data rate to be used in a communication channel, having a particular SNR, that achieves error free transmission through the communication channel. In other words, the Shannon limit is the theoretical bound for channel capacity for a given modulation and code rate.

Generally speaking, within the context of communication systems that employ ECCs, there is a first communication device at one end of a communication channel with encoder capability and second communication device at the other end of the communication channel with decoder capability. In many instances, one or both of these two communication devices includes encoder and decoder capability (e.g., within a bi-directional communication system). ECCs can be applied in a variety of additional applications as well, including those that employ some form of data storage (e.g., hard disk drive (HDD) applications and other memory storage devices) in which data is encoded before writing to the storage media, and then the data is decoded after being read/retrieved from the storage media.

### BRIEF SUMMARY OF THE INVENTION

The present invention is directed to apparatus and methods of operation that are further described in the following Brief Description of the Several Views of the Drawings, the Detailed Description of the Invention, and the claims. Other features and advantages of the present invention will become apparent from the following detailed description of the invention made with reference to the accompanying drawings.

### BRIEF DESCRIPTION OF THE SEVERAL VIEWS OF THE DRAWINGS

FIG. 1 and FIG. 2 illustrate various embodiments of communication systems.

FIG. 3 illustrates an embodiment of an apparatus that is operative to perform matrix formatting and product code encoding.

FIG. 4 and FIG. 5 illustrate embodiments of row and column encoding of matrix formatted bits, respectively.

FIG. 6 illustrates an alternative embodiment of row and column encoding of matrix formatted bits.

FIG. 7 illustrates an alternative embodiment of an apparatus that is operative to perform matrix formatting and product code encoding.

FIG. 8 illustrates an embodiment of systematic bit encoding of various bit groups using a common code for all bit groups.

FIG. 9 illustrates an alternative embodiment of systematic bit encoding of various bit groups using two or more codes for the various bit groups.

FIG. 10 illustrates an alternative embodiment of systematic bit encoding of various bit groups using two or more codes for the various bit groups.

FIG. 11A and FIG. 11B illustrate alternative embodiments of systematic bit encoding of various bit groups using two or more codes for the various bit groups, and particularly showing encoding of more than one row or column in certain respective bit groups.

FIG. 12 illustrates an alternative embodiment of systematic bit encoding of various bit groups using two or more codes for the various bit groups, and particularly showing partial row and/or column encoding.

FIG. 13 illustrates an alternative embodiment of a communication system.

FIG. 14 illustrates yet an alternative embodiment of a communication system.

FIG. 15 illustrates an embodiment of concatenated coding, as performed within a communication device, using LDPC (Low Density Parity Check) and Reed-Solomon (RS) coding.

FIG. 16A illustrates an embodiment of method for performing binary product coding in conjunction with LDPC (Low Density Parity Check) coding.

FIG. 16B illustrates an embodiment of method for performing an implementation oriented Reed-Solomon (RS) coding in conjunction with LDPC (Low Density Parity Check) coding.

FIG. 17A illustrates an embodiment of method for performing combined product and LDPC coding.

FIG. 17B illustrates an embodiment of an alternative method for performing combined product and LDPC coding.

FIG. 18 illustrates an embodiment of a method for performing concatenated coding both using LDPC (Low Density Parity Check) and Reed-Solomon (RS) coding.

### DETAILED DESCRIPTION OF THE INVENTION

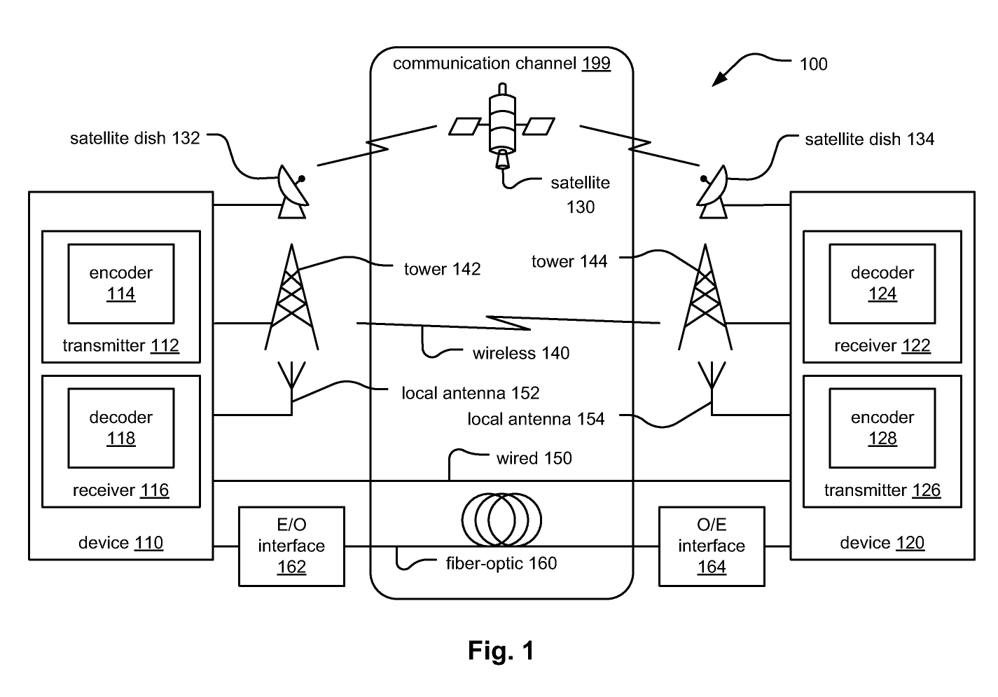

The goal of digital communications systems is to transmit digital data from one location, or subsystem, to another either error free or with an acceptably low error rate. As shown in FIG. 1, data may be transmitted over a variety of communications channels in a wide variety of communication systems: magnetic media, wired, wireless, fiber, copper, and other types of media as well.

FIG. 1 and FIG. 2 illustrate various embodiments of communication systems, 100 and 200, respectively.

Referring to FIG. 1, this embodiment of a communication system 100 is a communication channel 199 that communicatively couples a communication device 110 (including a transmitter 112 having an encoder 114 and including a receiver 116 having a decoder 118) situated at one end of the communication channel 199 to another communication device 120 (including a transmitter 126 having an encoder 128 and including a receiver 122 having a decoder 124) at the other end of the communication channel 199. In some embodiments, either of the communication devices 110 and 120 may only include a transmitter or a receiver. There are several different types of media by which the communication channel 199 may be implemented (e.g., a satellite communication channel 130 using satellite dishes 132 and 134, a wireless communication channel 140 using towers 142 and 144 and/or local antennae 152 and 154, a wired communication channel 150, and/or a fiber-optic communication channel 160 using electrical to optical (E/O) interface 162 and optical to electrical (O/E) interface 164)). In addition, more than one type of media may be implemented and interfaced together thereby forming the communication channel 199.

To reduce transmission errors that may undesirably be incurred within a communication system, error correction and channel coding schemes are often employed. Generally, these error correction and channel coding schemes involve the use of an encoder at the transmitter and a decoder at the receiver.

Any of the various types of coding described herein can be employed within any such desired communication system (e.g., including those variations described with respect to FIG. 1), any information storage device (e.g., hard disk drives (HDDs), network information storage devices and/or servers, etc.) or any application in which information encoding and/or decoding is desired.

Referring to the communication system 200 of FIG. 2, at a transmitting end of a communication channel 299, information bits 201 are provided to a transmitter 297 that is operable to perform encoding of these information bits 201 using an encoder and symbol mapper 220 (which may be viewed as being distinct functional blocks 222 and 224, respectively) thereby generating a sequence of discrete-valued modulation symbols 203 that is provided to a transmit driver 230 that uses a DAC (Digital to Analog Converter) 232 to generate a continuous-time transmit signal 204 and a transmit filter 234 to generate a filtered, continuous-time transmit signal 205 that substantially comports with the communication channel 299. The transmit driver 230 may perform any necessary front end processing of a signal received from a communication channel (e.g., including any one or digital to analog conversion, gain adjustment, filtering, frequency conversion, etc.) to generate the filtered, continuous-time transmit signal 205.

At a receiving end of the communication channel 299, continuous-time receive signal 206 is provided to an AFE (Analog Front End) 260 that includes a receive filter 262 (that generates a filtered, continuous-time receive signal 207) and an ADC (Analog to Digital Converter) 264 (that generates discrete-time receive signals 208). The AFE 260 may perform any necessary front end processing of a signal received from a communication channel (e.g., including any one or analog to digital conversion, gain adjustment, filtering, frequency conversion, etc.) to generate a digital signal provided to a metric generator 270 that generates a plurality of metrics corresponding to a particular bit or symbol extracted from the received signal. The metric generator 270 calculates metrics 209 (e.g., on either a symbol and/or bit basis) that are employed by a decoder 280 to make best estimates of the discrete-valued modulation symbols and information bits encoded therein 210.

The decoders of either of the previous embodiments may be implemented to include various aspects and/or embodiment of the invention therein. In addition, several of the following Figures describe other and particular embodiments (some in more detail) that may be used to support the devices, systems, functionality and/or methods that may be implemented in accordance with certain aspects and/or embodiments of the invention.

It is noted that various types of error correction codes (ECCs) may be employed herein. For example, any one or more of any type or variant of Reed-Solomon (RS) code, turbo code, turbo trellis code modulation (TTCM) code, LDPC (Low Density Parity Check) code, BCH (Bose and Ray-Chaudhuri, and Hocquenghem) code, etc. Moreover, as will be seen in various embodiments herein, more than one ECC and/or more than one type of ECC may be employed when generating a single encoded signal in accordance with the principles presented herein. For example, certain of the embodiments presented herein operate as product codes, in which an ECC is employed more than once or more than one type of ECC is employed (e.g., a first ECC during a first time and a second ECC at a second time) to generate an encoded signal.

Moreover, it is noted that both systematic encoding and non-systematic encoding may be performed in accordance with the various principles presented herein. Systematic encoding preserves the information bits being encoded and generates corresponding redundancy/parity bits (i.e., redundancy and parity may be used interchangeably herein); for example, the information bits being encoded are explicitly shown/represented in the output of non-systematic encoding. Non-systematic encoding does not necessarily preserve the information bits being encoded and generates coded bits that inherently include redundancy parity information therein; for example, the information bits being encoded need not be explicitly shown/represented in the output of non-systematic encoding. While many of the embodiments shown herein refer to systematic encoding, it is note that non-systematic encoding may alternatively, be performed in any embodiment without departing from the scope and spirit of the invention.

Certain embodiments of communication device and methods operating in accordance with the principles presented herein are designed to maximize coding gain as high as possible while maintaining a reasonable or acceptable hardware complexity and power consumption. Moreover, certain embodiments (e.g., to be compliant in accordance with a certain standard or communication protocol), certain constraints such as bit error rate (BER) or block error rate (BLER), redundancy rate or code rate, bit rates, throughput, etc.

For example, one embodiment that operates in accordance with a 100 Gbps (Giga-bits per second) bit rate targets a BER in the range of 1×10⁻¹⁴ or 1×10⁻¹⁵, and has a fixed redundancy rate of 16/239 or 6.69%.

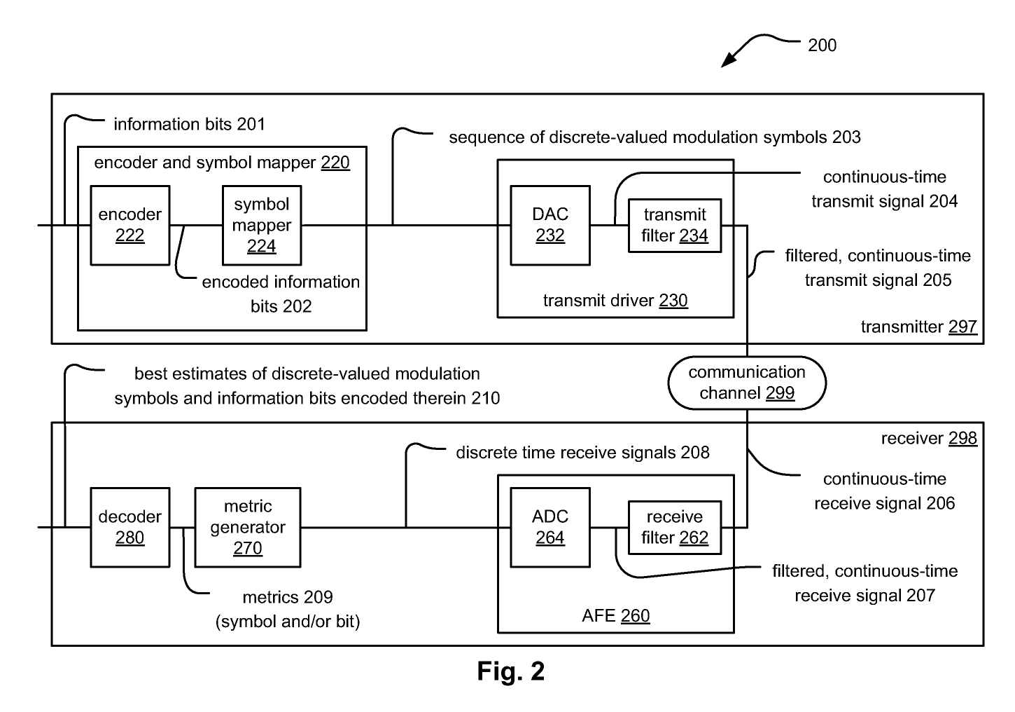

FIG. 3 illustrates an embodiment of an apparatus 300 that is operative to perform matrix formatting and product code encoding. In this embodiment, an information bit sequence (e.g., including bits 1 through n as depicted by b(1), b(2), and so on up to b(n)) is provided to a matrix formatting module 310. The matrix formatting module 310 operates by selecting/arranging the information bit sequence into a desired format/pattern. For example, the information bit sequence may be firstly arranged into information bit groups (e.g., first information bit group including bits b(1) through b(x), second information bit group including bits b(x+1) through b(2x), and so on until an m-th information bit group including bits b((m−1)x+1) through b(n)[end of original information bit sequence]), and each information bit group then is arranged appropriately into rows (e.g., row placement) thereby generating matrix formatted bits. The columns formed by the appropriate arrangement of the rows are themselves the columns of the matrix formatted bits.

An encoder 320 selectively encodes the matrix formatted bits thereby generating encoded bits (e.g., an encoded bit sequence). For example, parity bits corresponding to the matrix formatted bits are generated in accordance with encoding.

In some embodiments, the encoder 320 is a product code encoder 320a. A product code encoder may be viewed as being a two dimensional encoder that operates in a first dimension, and then operates in a second dimension. Each of these two dimensions may employ a common ECC, or they may employ different ECCs. In even another embodiment, different respective ECCs may be employed for the respective rows and/or columns of the matrix formatted bits. In one embodiment, the first dimension is performed using a row encoder 321a, and the second dimension is performed using a column encoder 322a.

It is noted that a common ECC may be employed when encoding the separate rows of bits within the matrix formatted bits; alternatively, different ECCs may be employed when encoding the various rows of bits within the matrix formatted bits. Similarly, a common ECC may be employed when encoding the separate columns of bits within the matrix formatted bits; alternatively, different ECCs may be employed when encoding the various columns of bits within the matrix formatted bits.

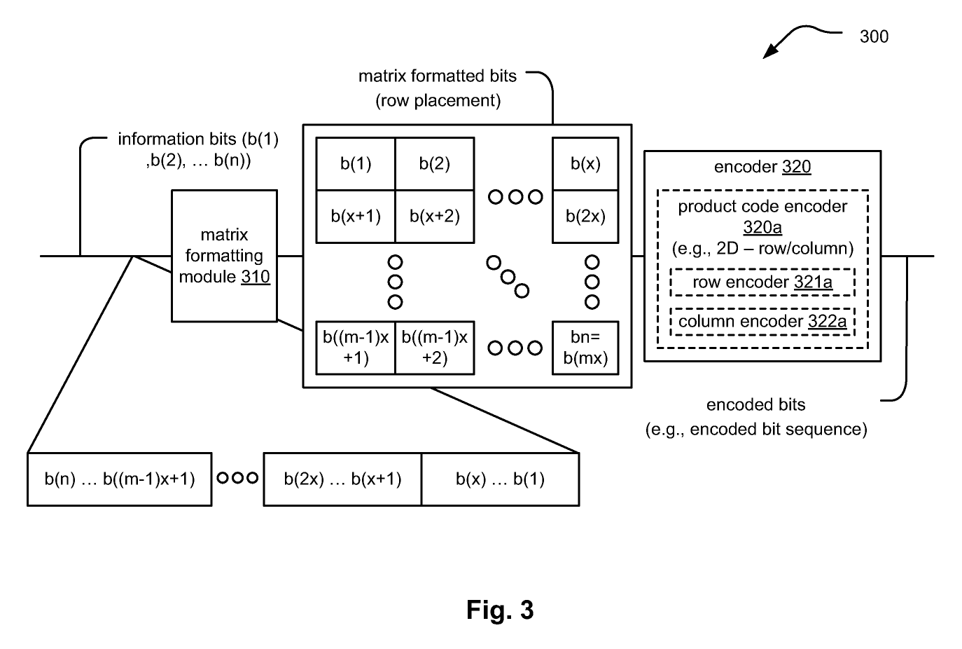

FIG. 4 and FIG. 5 illustrate embodiments, 400 and 500, respectively, of row and column encoding of matrix formatted bits, respectively. These embodiments 400 and 500 depict systematic encoding, but again, non-systematic encoding can be employed in alternative embodiments without departing from the scope and spirit of the invention.

Referring to embodiment 400 of FIG. 4, an information bit row/group 1 (R1) shown as including bits b(1) through b(x) undergo encoding in accordance with an ECC to generate parity bit row/group 1 (P(R1)). For each of the other rows of the matrix formatted bits (e.g., shown in FIG. 3), the corresponding information bit row/group undergoes encoding in accordance with an ECC to generate a corresponding parity bit row/group.

Referring to embodiment 500 of FIG. 5, an information bit column/group 1 (C1) shown as including bits b(1) through b((m−1)x+1) undergo encoding in accordance with an ECC to generate parity bit column/group 1 (P(C1)). For each of the other columns of the matrix formatted bits (e.g., shown in FIG. 3), the corresponding information bit column/group undergoes encoding in accordance with an ECC to generate a corresponding parity bit column/group.

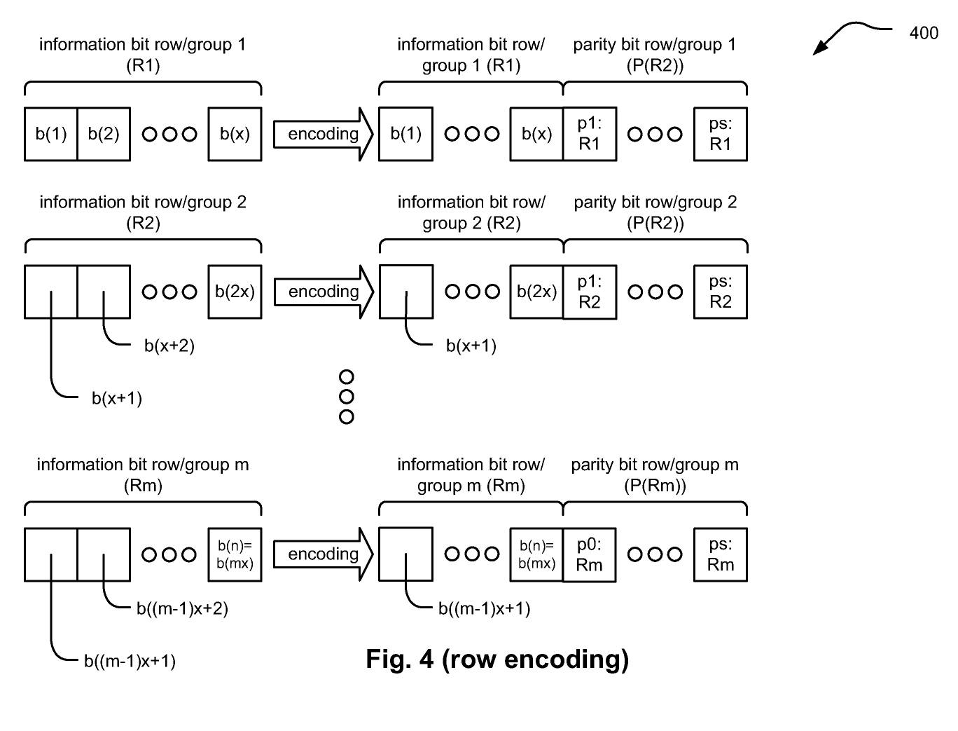

FIG. 6 illustrates an alternative embodiment 600 of row and column encoding of matrix formatted bits. The embodiment 600 shows the relationship between matrix formatted bits and the parity bits generated in accordance with row encoding and column encoding.

As can be seen when comparing the matrix formatted bits on the left hand side with the resulting encoded matrix on the right hand side, the matrix formatted bits is included in the resulting encoded matrix along with parity bits generated in accordance with row encoding (i.e., located to the right hand side of the matrix formatted bits, shown as including s parity bits each) as well as parity bits generated in accordance with column encoding (i.e., located below the matrix formatted bits, shown as including t parity bits each). It is noted that t may equal s in some embodiments, or t may be different be different values in other embodiments.

It is also noted that column encoding may subsequently be performed on the parity bits generated in accordance with row encoding to generate additional parity bits included below those parity bits (i.e., located in lower right hand corner of the resulting encoded matrix). Alternatively, it is also noted that row encoding may subsequently be performed on the parity bits generated in accordance with column encoding to generate parity bits included to the right hand side of those parity bits (i.e., located in lower right hand corner of the resulting encoded matrix).

In an even alternative embodiment, a combination of column encoding performed on the parity bits generated in accordance with row encoding and column encoding (i.e., some of the parity bits located in lower right hand corner of the resulting encoded matrix may be generated by encoding the parity bits located above and some of the parity bits located in lower right hand corner of the resulting encoded matrix may be generated by encoding the parity bits located to the left). In even another embodiment, it is also possible to have all of the generated parity bits from row encoding and column encoding appended after the source data sequence.

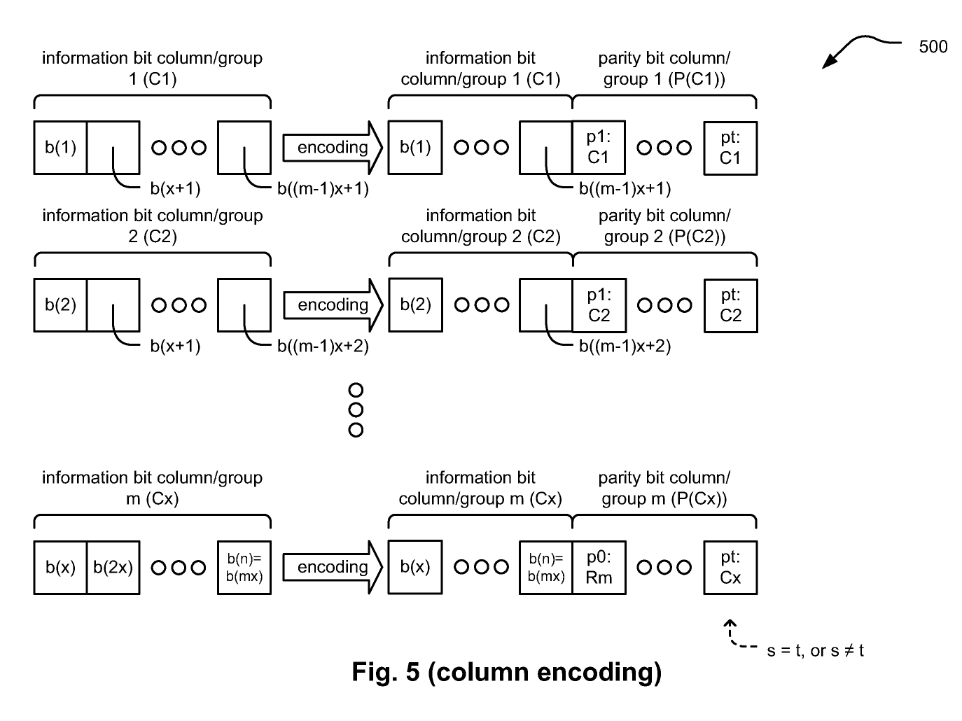

FIG. 7 illustrates an alternative embodiment of an apparatus 700 that is operative to perform matrix formatting and product code encoding. This embodiment is somewhat analogous to the apparatus 300 of FIG. 3 with at least one difference being that the resulting matrix formatted bits are arranged in accordance with column placement.

In this embodiment, an information bit sequence (e.g., including bits 1 through n as depicted by b(1), b(2), and so on up to b(n)) is provided to a matrix formatting module 710. The matrix formatting module 710 operates by selecting/arranging the information bit sequence into a desired format/pattern. For example, the information bit sequence may be firstly arranged into information bit groups (e.g., first information bit group including bits b(1) through b(x), second information bit group including bits b(x+1) through b(2x), and so on until an nth information bit group including bits b((m−1)x+1) through b(n)[end of original information bit sequence]), and each information bit group then is arranged appropriately into columns (e.g., column placement) thereby generating matrix formatted bits.

An encoder 720 selectively encodes the matrix formatted bits thereby generating encoded bits (e.g., an encoded bit sequence). For example, parity bits corresponding to the matrix formatted bits are generated in accordance with encoding.

In some embodiments, the encoder 720 is a product code encoder 720a. A product code encoder may be viewed as being a two dimensional encoder that operates in a first dimension, and then operates in a second dimension. Each of these two dimensions may employ a common ECC, or they may employ different ECCs. In one embodiment, the first dimension is performed using a row encoder 721a, and the second dimension is performed using a column encoder 722a.

Again, it is noted that a common ECC may be employed when encoding the separate rows of bits within the matrix formatted bits; alternatively, different ECCs may be employed when encoding the various rows of bits within the matrix formatted bits. Similarly, a common ECC may be employed when encoding the separate columns of bits within the matrix formatted bits; alternatively, different ECCs may be employed when encoding the various columns of bits within the matrix formatted bits.

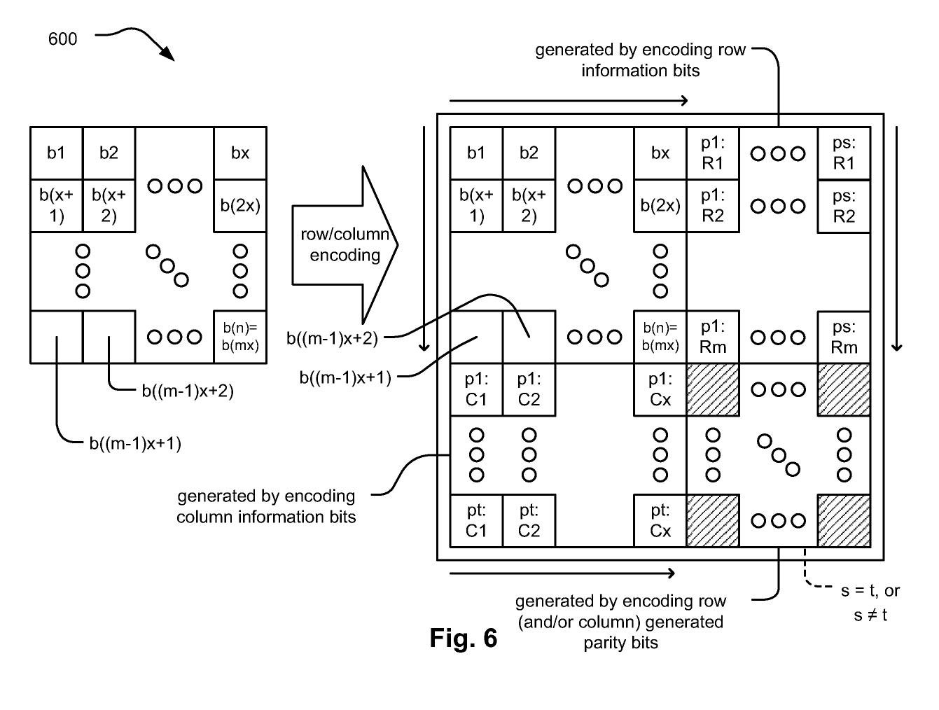

FIG. 8 illustrates an embodiment 800 of systematic bit encoding of various bit groups using a common code for all bit groups. Information bits are provided to an encoder 810 and encoded bits are output there from (i.e., information bits+redundancy/parity bits in a systematic encoding embodiment).

The information bits are firstly arranged into information bit groups (e.g., first information bit group (GO) including x bits, second information bit group (G1) including x bits, and so on up to information bit group (Gn) including x bits).

Each of the information bit groups undergoes encoding using a common ECC to generate corresponding parity bit groups (each including y bits). Certain of the generated coded bits (e.g., information bits+parity bits) are arranged and undergo row encoding. Other of the generated coded bits (e.g., information bits+parity bits) are arranged and undergo column encoding.

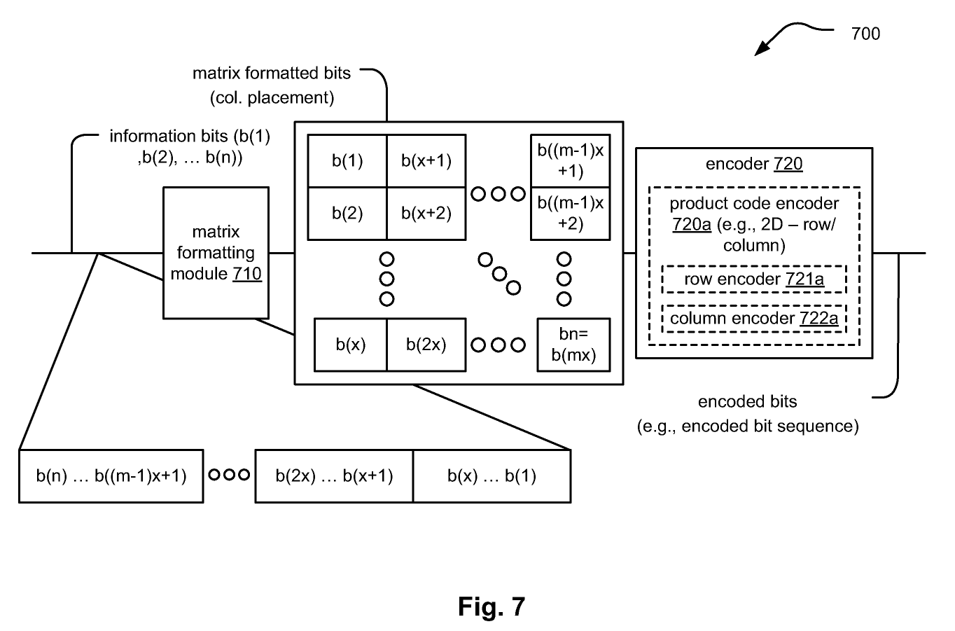

FIG. 9 illustrates an alternative embodiment 900 of systematic bit encoding of various bit groups using two or more codes for the various bit groups.

Information bits are provided to a multi-code encoder 910 and encoded bits are output there from (i.e., information bits+redundancy/parity bits in a systematic encoding embodiment). The multi-code encoder 910 includes and is operative to employ a different ECC at different times to encode different information bits.

The information bits are firstly arranged into information bit groups (e.g., first information bit group (G0) including x bits, second information bit group (G1) including x bits, and so on up to information bit group (Gn) including x bits—in other words, each of the various information bit groups including a same number of bits, x, though the respective information bits in each group may of course be different information bits).

Each of the information bit groups undergoes encoding using a respective ECC to generate corresponding parity bit groups. For example, the first coded bits includes information bit group (G0) (x bits) and parity bit group P0 (y1 bits). The second coded bits includes information bit group (G1) (x bits) and parity bit group P1 (y1 bits). The first coded bits and the second coded bits are generated using a first ECC (e.g., each of the information bit groups (G0) and (G1) including a same number of bits, and each of the parity bit groups (P0) and (P1) also including a respective same number of bits). However, in this embodiment using a multi-code encoder 910, the coded bits including information bit group (Gn) (x bits) undergo encoding thereby generating parity bit group Pn (yn bits); these information bit group (Gn) (x bits) bits are generated using a second ECC (e.g., that has a different amount of redundancy that the first ECC used to generate the parity bit groups (P0) and (P1)).

If desired, to ensure that a same number of bits are included within each information bit group and each parity bit group (or for any other purpose, e.g., to ensure the overall coded bits meet some constraint or requirement), fill bits may be employed. The placement of these fill bits may be anywhere within that respective sequence (e.g., at the end, at the beginning, interspersed therein in accordance with some pattern). The fill bits may be all zero-valued bits, they may be cyclic redundancy check (CRC) bits, checksum bits, special flag bits to indicate an occurrence of some issue, etc.). In particular, these fill bits may be inserted before encoding or after encoding for one or more of the code groups.

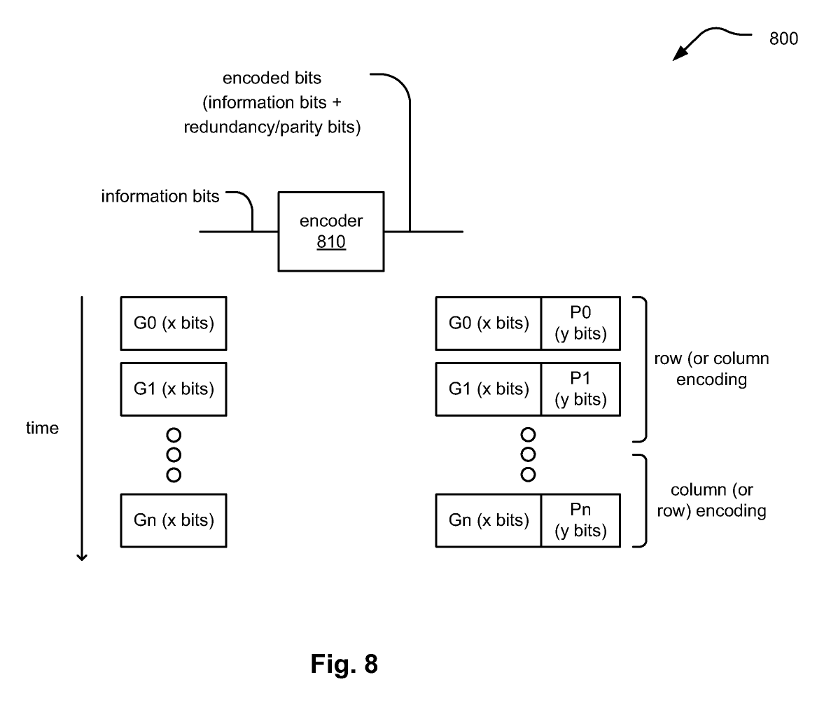

FIG. 10 illustrates an alternative embodiment 1000 of systematic bit encoding of various bit groups using two or more codes for the various bit groups.

Information bits are provided to a multi-code encoder 1010 and encoded bits are output there from (i.e., information bits+redundancy/parity bits in a systematic encoding embodiment). The multi-code encoder 1010 includes and is operative to employ a different ECC at different times to encode different information bits.

The information bits are firstly arranged into information bit groups (e.g., first information bit group (G0) including x1 bits, second information bit group (G1) including x2 bits, and so on up to information bit group (Gn) including xn bits).

The first coded bits includes information bit group (G0) (x1 bits) and parity bit group P0 (y1 bits) as generated by a first ECC. The second coded bits includes information bit group (G1) (x2 bits) and parity bit group P1 (y2 bits) as generated by a second ECC. The nth coded bits includes information bit group (Gn) (xn bits) and parity bit group Pn (yn bits) as generated by an nth ECC.

If desired, to ensure that a same number of bits is included within each information bit group and each parity bit group (or for any other purpose, e.g., to ensure the overall coded bits meet some constraint or requirement), fill bits may be employed. The placement of these fill bits may be anywhere within that respective sequence (e.g., at the end, at the beginning, interspersed therein in accordance with some pattern). The fill bits may be all zero-valued bits, they may be cyclic redundancy check (CRC) bits, checksum bits, special flag bits to indicate an occurrence of some issue, etc. The fill bits may be different in each of the respective coded bit groups, and certain of the coded bit groups may include no fill bits whatsoever.

It is also noted that, while certain embodiments presented herein do in fact deal with the concatenation of one or more product codes (e.g., such as using any desired singular BCH or singular RS code, or using any desired combination of BCH and/or RS codes) with one or more LDPC codes, it is also noted that other embodiments may also deal with the concatenation of one or more RS codes with one or more LDPC codes without departing from the scope and spirit of the invention.

Generally speaking, concatenation of multiple ECCs may be viewed as employing one or more ECCs (e.g., implemented such as an inner code) in conjunction with one or more additional ECCs (e.g., implemented such as an outer code) [which may be the same or different than the previous one or more ECCs of the inner code].

Information bits may initially be encoded thereby generating parity bits and all of those information and parity bits may undergo processing thereby generating matrix formatted bits (e.g., the information and parity bits being arranged thereby forming a matrix). Then, each outer code covers one or more rows (and possibly also including a partial row), and each inner code covers one or more columns (and possibly also including a partial column). Fill bits may be inserted in one or more or the rows (or columns) before (or after) encoding as well without departing from the scope and spirit of the invention. Such fill bits may also be a CRC checksum for a portion of or for the entire matrix formatted bits. Generally speaking, such fill bits may be included in accordance with any desired manner including any predetermined bit patterns.

A Type-II SP-BCH (alternatively, referred to as a super product BCH code) consists of 987 column BCH(992, 960, t=3) codes and 960 row BCH(987, 956, t=3) codes. Two extra redundant bits are added for each column code. One extra bit is added for each row code. The two extra bits are CRC checksums of each code group. The primitive polynomial used for the CRC computation is x̂2+x+1. Alternatively, a primitive polynomial of higher orders may be employed while selectively using two bits from the CRC checksum. One extra bit added for BCH(987, 956, t=3) code groups can be an even or odd parity bit for the source data of the code group.

A Type-III super product code consists of 992 column BCH(987, 956, t=3) codes and 956 row BCH(992, 960, t=3) codes. Two extra redundant bits are added for each row codes. One extra bit is added for each column code.

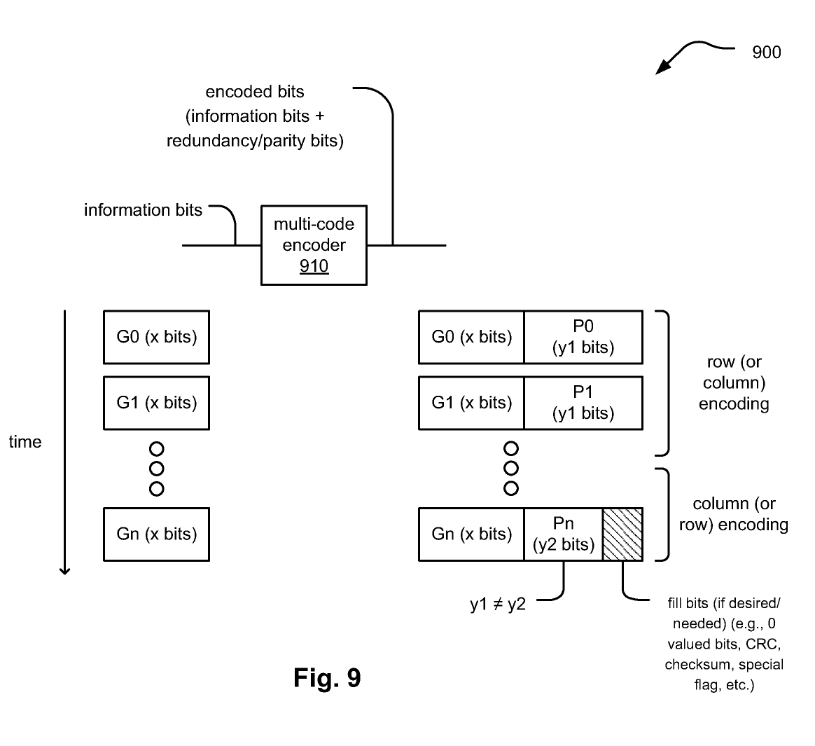

FIG. 11A and FIG. 11B illustrate alternative embodiments 1100 and 1101, respectively, of systematic bit encoding of various bit groups using two or more codes for the various bit groups, and particularly showing encoding of more than one row or column in certain respective bit groups. In desired embodiments, it is noted that various ECCs may be employed for encoding a group of bits composed of more than one row of matrix formatted bit.

As also mentioned with respect to other embodiments, a same ECC may be employed for encoding more than one bit group. Alternatively, different ECCs may respectively be employed for encoding different bit groups (e.g., a different ECC may be employed for each respective bit group; alternatively, a first ECC may be employed for a first plurality of bit groups and a second ECC may be employed for a second plurality of bit groups and so on, etc.).

In other words, bits from more than one row may be used to form a particular bit group, or bits from more than one column may be used to form a particular bit group. For example, the embodiment 1100 of FIG. 11A depicts how two rows and two columns are respectively included thereby forming respective bit groups for subsequently undergoing encoding using one or more ECCs. For example, the embodiment 1101 of FIG. 11B depicts how three rows and three columns are respectively included thereby forming respective bit groups for subsequently undergoing encoding using one or more ECCs. Of course, generally speaking, x number of rows or columns (where x is an integer) may be employed to form respective bit groups for subsequently undergoing encoding using one or more ECCs.

It is also noted that different bit groups may each include different numbers of rows included therein thereby generating respective bit groups (e.g., a first bit group may be composed of bits from a first number of rows (or columns), and a second bit group may be composed of bits from a second number [being different than the first number] of rows (or columns), etc.).

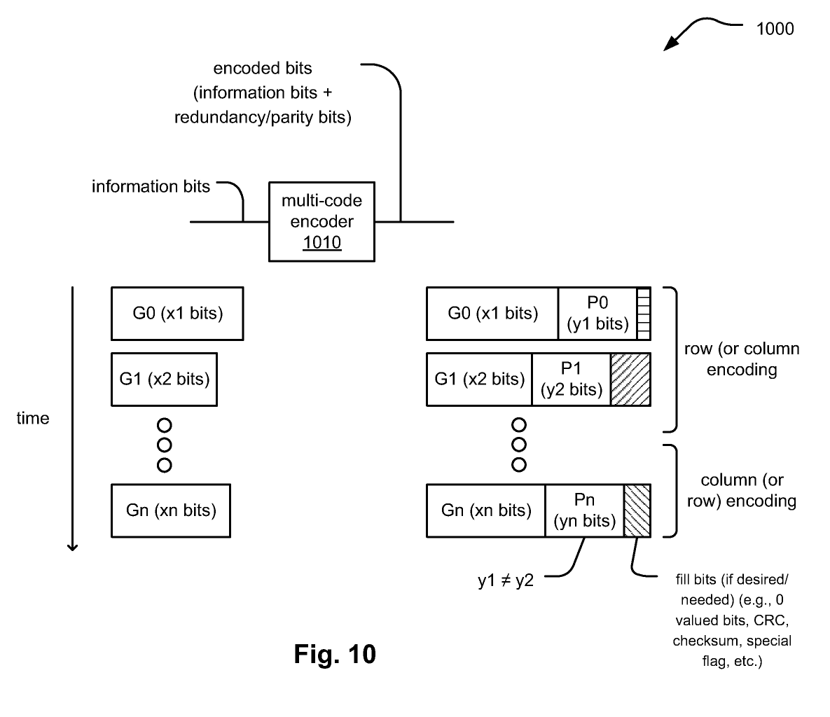

FIG. 12 illustrates an alternative embodiment 1200 of systematic bit encoding of various bit groups using two or more codes for the various bit groups, and particularly showing partial row and/or column encoding. This diagram shows how more than one row (or column) may be employed in forming respective bit groups as well as including a partial row (or partial column) in a particular group. For example, each bit group may be composed of bits from a portion of a row (or column) as well without departing from the scope and spirit of the invention.

Also, while many of the embodiments shown herein include contiguously formed bit groups (e.g., bit groups formed by adjacent one or more rows [or columns] and/or a partial row [or column]), it is noted that the selection of bits from among a total set of bits (e.g., matrix formatted bits in some embodiments) may be made in accordance with any desired manner including selecting bits from among the total set of bits in accordance with a predetermined pattern.

For example, considering some specific example, a first bit group may be formed by including bits from 7 columns or alternatively, 8 columns plus 15 bits from an additional row. In an even another example, a second bit group may be formed by including bits from 9 columns or alternatively, 4 columns plus 53 bits from an additional column. A designer has wide latitude to form the various bit groups to be employed in accordance with the various principles herein.

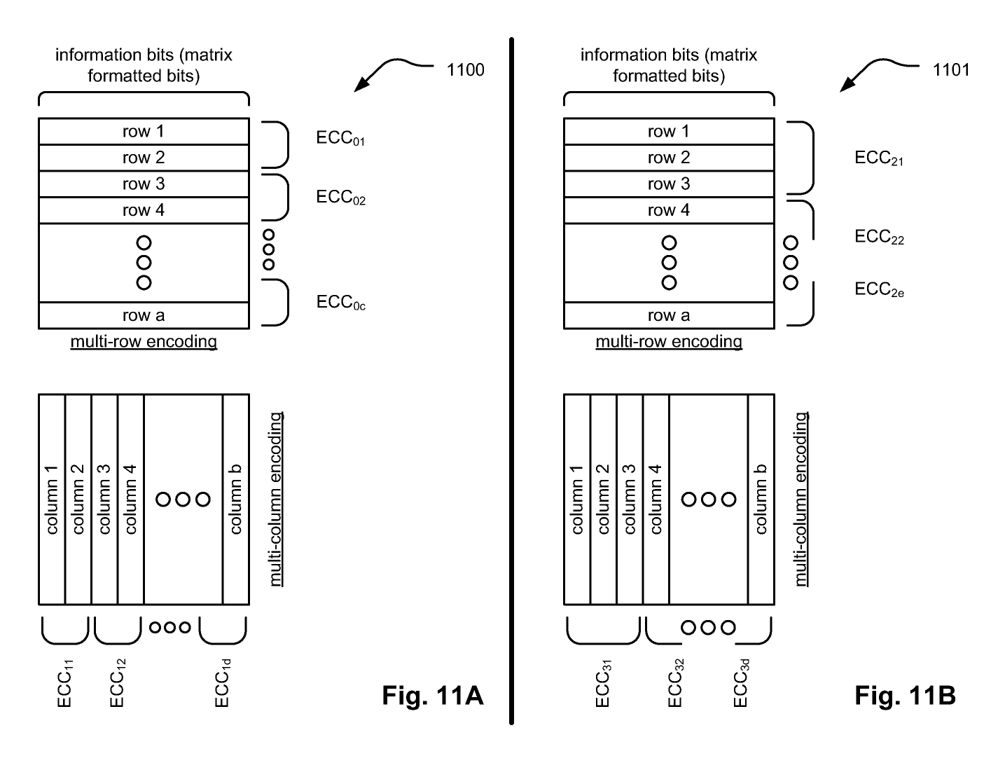

FIG. 13 illustrates an alternative embodiment of a communication system 1300. Initially, information bits 1301a are provided to an outer code encoder, that is implemented as a product code encoder 1305a. The encoded bits output from the product code encoder 1305a are provided to an LDPC encoder 1310a from which at least one LDPC codeword is output (i.e., shown as being an inner code encoder). This one or more LDPC codewords is provided to an interleaver (t)/symbol mapper 1320a implemented to perform any desired combination of interleaving and symbol mapping (which may symbol map different symbols to different modulations (i.e., constellations with respective mappings of the constellation points therein).

It is noted that the operational characteristics of the LDPC encoder 1310a in combination with the interleaver (π)/symbol mapper 1320a can be performed with any desired combination. A modulator 1330a (e.g., which may be viewed as being an embodiment of a transmit driver) performs any necessary modification (e.g., frequency conversion, gain adjustment, filtering, etc.) to the discrete sequence of symbols output from the interleaver (t)/symbol mapper 1320a to generate a continuous time signal that comports with the characteristics of communication channel 1399 (e.g., including filtering, digital to analog conversion, frequency conversion, gain adjustment, etc.).

A demodulator 1330b receives the signal from the communication channel 1399 (e.g., the signal may have incurred certain effects including noise, etc.) and perform demodulation thereon. This may involve the calculation of certain metrics (e.g., by a metric generator 1331b) and symbol de-mapping (e.g., by a symbol de-mapper 1321b) for use in subsequent decoding. This may also involve any other demodulation function (e.g., as shown by reference numeral 1339b) including filtering, analog to digital conversion, frequency conversion, gain adjustment, etc.

After undergoing the demodulation operations, the bit sequence generated there from undergoes de-interleaving in de-interleaver (π⁻¹) 1322b. An LDPC decoder 1310b (shown as an inner code decoder) then decodes the output from the de-interleaver (π⁻¹) 1322b to generate a sequence of estimated bits that subsequently undergo outer decoding in outer decoder 1305b from which estimates of the information bits 1301b are generated.

Similarly as the outer code encoder is implemented using a product code encoder, a product code decoder 1305b (shown as an outer code decoder) is chosen to correspond to the type of code employed within the product code encoder 1305a. Estimates of the original information bits 1301b are output from the product code decoder 1305b.

With respect to the embodiment of FIG. 13, the Applicant also respectfully points out that a matrix formatting module 1399a may be implemented within a transmitter communication device (that may include all of the components shown before the communication channel 1399) at a first end of the communication channel 1399, and a matrix formatting module 1399b may be implemented within a receiver communication device (that may include all of the components shown after the communication channel 1399) at a second end of the communication channel 1399. The respective matrix formatting modules 1399a and 1399b are operative to perform formatting of information bits, coded bits, interleaved bits, etc. based on matrix formatting in accordance with the principles described herein as well as perform coordination between one or more of the various modules within the respective transmitter and receiver communication devices, respectively. In certain embodiments, the matrix formatting module 1399a may be communicatively coupled to one or more of the components shown within a transmitter device, and the matrix formatting module 1399b may be communicatively coupled to one or more of the components shown within a receiver device. The respective matrix formatting modules 1399a and 1399b may also operate in accordance with coordination among one another without departing from the scope and spirit of the invention. In this embodiment, as well as other embodiments described herein, various embodiments may include more or fewer modules and/or functional blocks without departing from the scope and spirit of the invention.

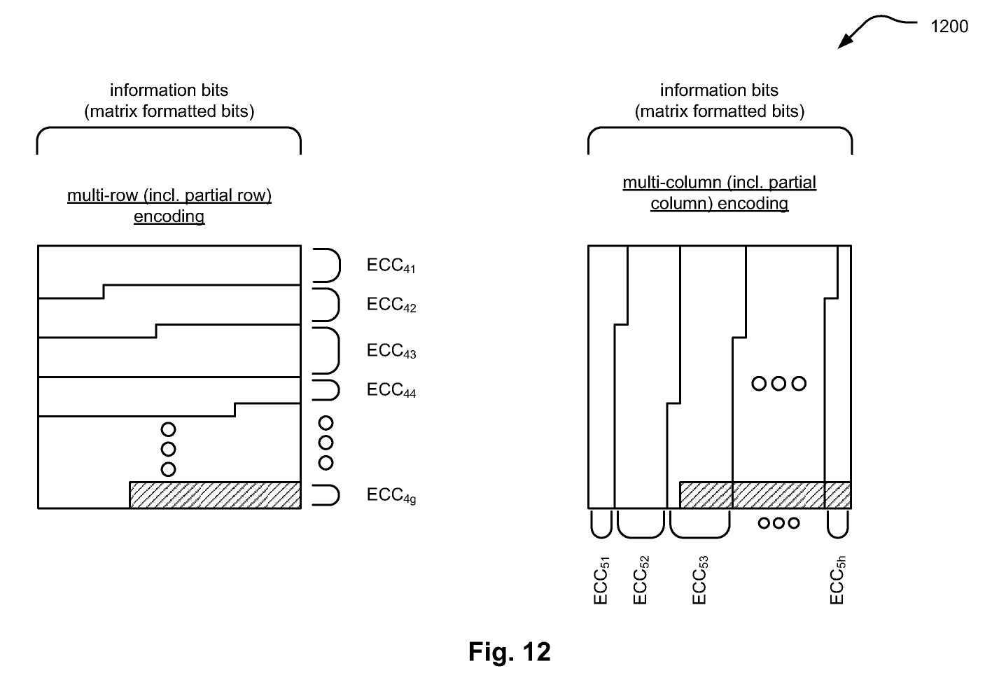

FIG. 14 illustrates yet an alternative embodiment of a communication system 1400. Initially, information bits 1401a are provided to an outer code encoder, that is implemented as a product code encoder 1405a. The encoded bits output from the product code encoder 1405a are provided to an LDPC encoder 1410a from which at least one LDPC codeword is output (i.e., shown as being an inner code encoder). This one or more LDPC codewords is provided to an interleaver (t)/symbol mapper 1420a implemented to perform any desired combination of interleaving and symbol mapping (which may symbol map different symbols to different modulations (i.e., constellations with respective mappings of the constellation points therein).

It is noted that the operational characteristics of the LDPC encoder 1410a in combination with the interleaver (π)/symbol mapper 1420a can be performed with any desired combination. A modulator 1430a (e.g., which may be viewed as being an embodiment of a transmit driver) performs any necessary modification (e.g., frequency conversion, gain adjustment, filtering, etc.) to the discrete sequence of symbols output from the interleaver (π)/symbol mapper 1420a to generate a continuous time signal that comports with the characteristics of communication channel 1499 (e.g., including filtering, digital to analog conversion, frequency conversion, gain adjustment, etc.).

A demodulator 1430b receives the signal from the communication channel 1499 (e.g., the signal may have incurred certain effects including noise, etc.) and perform demodulation thereon. This may involve the calculation of certain metrics (e.g., by a metric generator 1431b) and symbol de-mapping (e.g., by a symbol de-mapper 1421b) for use in subsequent decoding. This may also involve any other demodulation function (e.g., as shown by reference numeral 1439b) including filtering, analog to digital conversion, frequency conversion, gain adjustment, etc.

After undergoing the demodulation operations, the bit sequence generated there from undergoes de-interleaving in de-interleaver (π⁻¹) 1422b. An LDPC decoder 1410b (shown as an inner code decoder) then decodes the output from the de-interleaver (π⁻¹) 1422b to generate a sequence of estimated bits that subsequently undergo outer decoding in outer decoder 1405b from which estimates of the information bits 1401b are generated.

Similarly as the outer code encoder is implemented using a product code encoder, a product code decoder 1405b (shown as an outer code decoder) is chosen to correspond to the type of code employed within the product code encoder 1405a. Estimates of the original information bits 1401b are output from the product code decoder 1405b.

With respect to the embodiment of FIG. 14, the Applicant also respectfully points out that a matrix formatting module 1499a may be implemented within a transmitter communication device (that may include all of the components shown before the communication channel 1499) at a first end of the communication channel 1499, and a matrix formatting module 1499b may be implemented within a receiver communication device (that may include all of the components shown after the communication channel 1499) at a second end of the communication channel 1499. The respective matrix formatting modules 1499a and 1499b are operative to perform formatting of information bits, coded bits, interleaved bits, etc. based on matrix formatting in accordance with the principles described herein as well as perform coordination between one or more of the various modules within the respective transmitter and receiver communication devices, respectively. In certain embodiments, the matrix formatting module 1499a may be communicatively coupled to one or more of the components shown within a transmitter device, and the matrix formatting module 1499b may be communicatively coupled to one or more of the components shown within a receiver device. The respective matrix formatting modules 1499a and 1499b may also operate in accordance with coordination among one another without departing from the scope and spirit of the invention. In this embodiment, as well as other embodiments described herein, various embodiments may include more or fewer modules and/or functional blocks without departing from the scope and spirit of the invention.

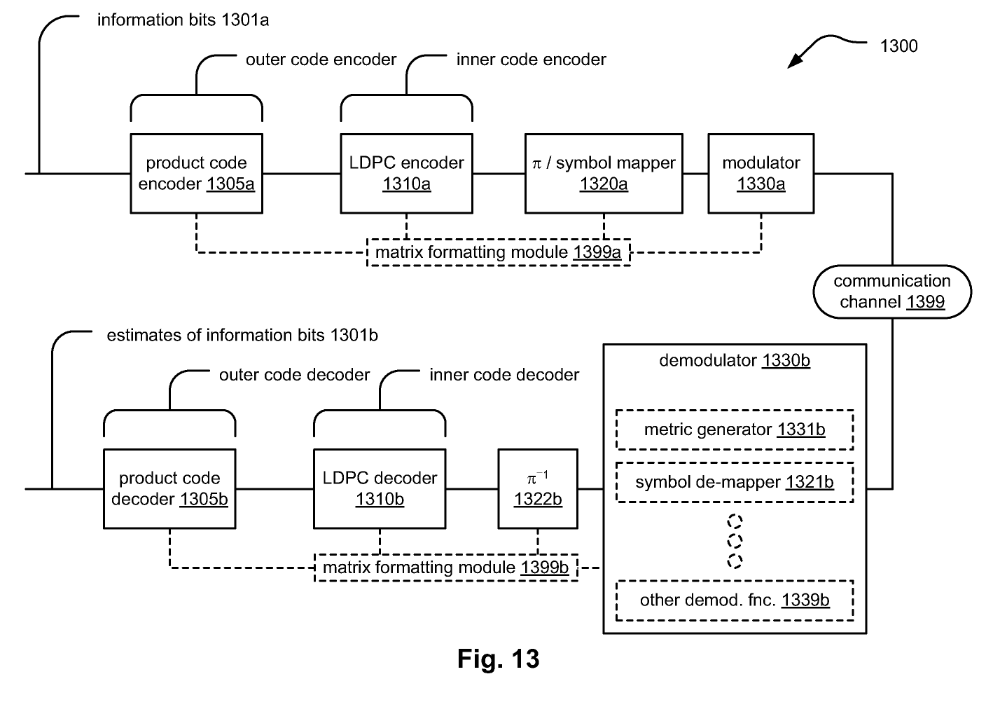

FIG. 15 illustrates an embodiment 1500 of concatenated coding, as performed within a communication device, using LDPC (Low Density Parity Check) and Reed-Solomon (RS) coding.

For soft-decision decoding systems, LDPC codes may be employed. For example, in accordance with LDPC codes, soft information and/or soft decisions corresponding to information bits encoded within a signal are calculated and, later, hard decisions corresponding to those soft information and/or soft decisions may be made. In contrast, hard decision decoding directly makes hard decisions corresponding to information bits encoded within a signal. To achieve a very low bit error rate (BER), block codes such as high-rate Reed-Solomon (RS) or BCH codes (as invented independently by (1) Hocquenghem and by (2) Bose and Ray-Chaudhuri—which may generally be referred to as BCH (Bose, Ray-Chaudhuri, Hocquenghem) codes) may be employed as outer codes. Herein, a product code is employed as an outer code to be concatenated with one or more (e.g., multiple) LDPC codes to achieve optimal decoding performance. For instance, a Type-III SP-BCH code may be employed as an outer code. As can be seen, a RS code or a BCH code (binary product code) may be concatenated with an LDPC code in accordance with at least two possible schemes in accordance with the principles that are described herein.

The 992 column codes are partitioned into 32 interleaved groups. Each group consists of 31 columns. Each group is defined as source data to one LDPC code block or multiple interleaved LDPC code blocks. Each group is assigned to 2 interleaved LDPC code blocks. Hence, the source data length for an LDPC code will be 31×(987+1)/2=15314 bits.

If the product code takes 6.69% redundancy, the LDPC code will have a redundancy ratio of about 12.5%, which is a rate 8/9 code. Considering a shortened LDPC code, the LDPC code length can be set to be 15320=8×(383×5), which is good for max column weight of 5. In addition, the LDPC code (source) length can be 15328=1916×8=479×4×8, which is good for a maximum column weight of 4.

The final coded code length for LDPC codec will be 383×5×9=17235 in Case-I or 479×489=17244 in Case-II, respectively. Considering puncturing, 64 LDPC coded blocks will have a total length of

32×(17235−6)+32×(17235−7)=1102624 bits, or

32×(17244−14)+32×(17244−15)=1102688 bits.

The overall redundancy in Case-I will be (1102624−956×960−88)/956/960=20.13%.

The overall redundancy in Case-I will be (1102688−956×960−88)/956/960=20.14%.

As may be seen, the overall redundancy of such forward error correction (FEC) coding in accordance with a product code and an LDPC code may have an overall redundancy being approximately 20% (e.g., at or near 20% within some predetermined tolerance such as 1%, 3%, etc).

The kind of code is expected to achieve outstanding performance for very low target BER.

A Type-II code can be used as an outer code, BCH (987, 956)×BCH (992, 960), frame size=30 ODU sub-frames (30592). Outer codes used redundancy bits: 61344 bits, 97 spare bits, can be partially used as row/column CRC checksum or for punctured LDPC codes.

The product code matrix can be partitioned into multiple columns: 987=21×47, 47 LDPC codes, each one has a code size of 21×992=20832 bits. 20832=651×32, coded block size=651×36=23436, real code rate ˜=0.89. The overall rate=956×987/47/23436=0.8332. Overall redundancy ratio=20.0%.

Again, the overall redundancy of such FEC coding may have an overall redundancy being approximately 20% (e.g., at or near 20% within some predetermined tolerance such as 1%, 3%, etc).

LDPC code rate ˜=8/9. The sub-matrix size can be 651, 217, or 534, or some other size as preferred in a particular embodiment.

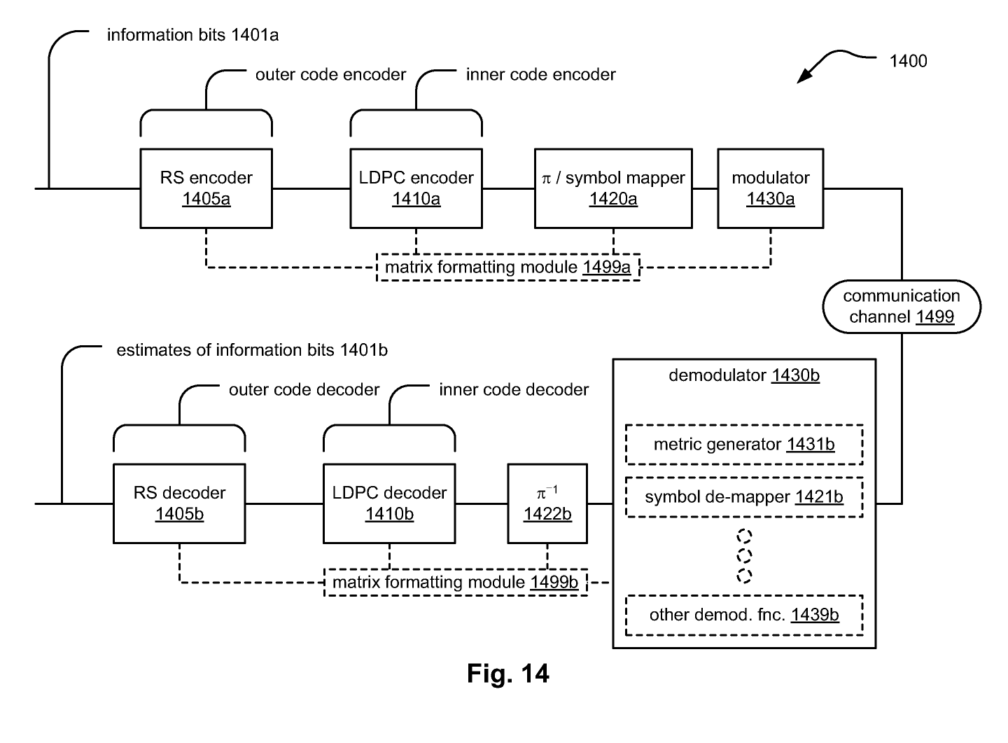

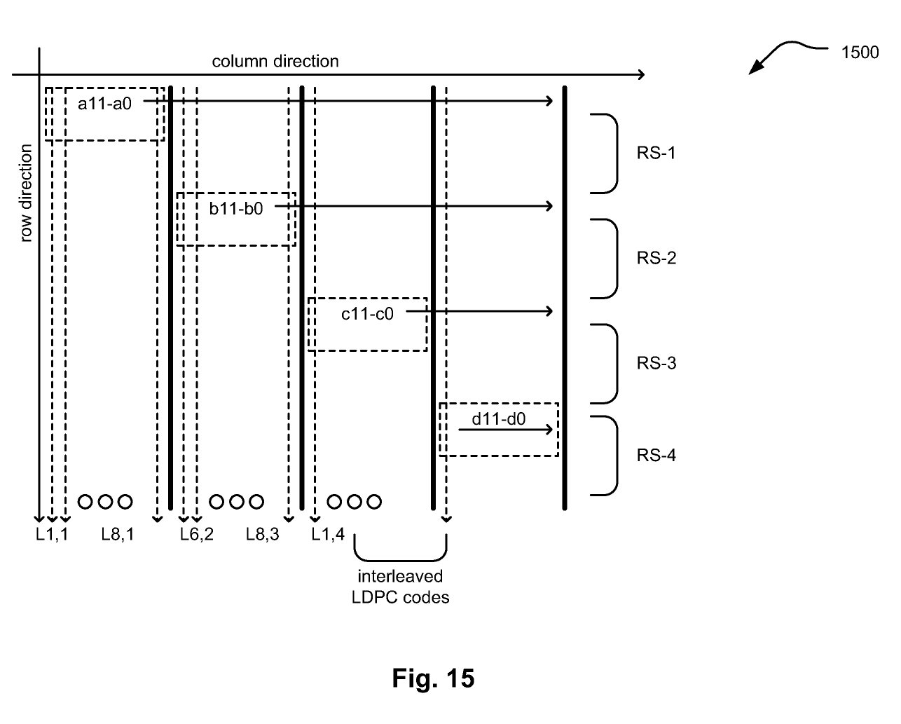

FIG. 16A illustrates an embodiment of method 1600 for performing binary product coding in conjunction with LDPC (Low Density Parity Check) coding.

Referring to method 1600 of FIG. 16A, the method 1600 begins by encoding information bits in accordance with a binary product code thereby generating product coded bits, as shown in a block 1610. This may be performed in accordance with row and column encoding thereby generating matrix formatted bits (e.g., arranged in rows and column). The method 1600 continues by encoding product coded bits in accordance with one or more LDPC codes thereby generating LDPC coded sequence, as shown in a block 1620.

The method 1600 then operates by partitioning LDPC coded sequence thereby generating symbol sequence, as shown in a block 1630. The method 1600 continues by modulating symbol sequence thereby generating signal that comports with a communication channel (e.g., a continuous time signal), as shown in a block 1640. The method 1600 continues by launching signal into communication channel, as shown in a block 1650.

A generic implementation-oriented RS+LDPC coding scheme is given as follows:

FIG. 16B illustrates an embodiment of method 1601 for performing an implementation oriented Reed-Solomon (RS) coding in conjunction with LDPC (Low Density Parity Check) coding.

The method 1601 operates by partitioning source data frame into a N(≧1) consecutive RS code blocks, as shown in a block 1611. This operates by partitioning the entire source data frame in to N (>=1, greater than or equal to 1) consecutive RS code blocks.

The method 1601 continues by arranging N or K1×N (K1≧1) code symbols in a row, as shown in a block 1611. This operates by arranging N or K1×N (K1>=1) code symbols in a row, and all parity symbols are arranged at the end of the corresponding source data block.

In some embodiments, the method operates by ensuring overall RS code symbols multiple of K1, as shown in a block 1621a. The overall coded RS code symbols is ensured to be a multiple of K1. If this cannot be performed straightforwardly, then code puncturing (e.g., deleting selected bits) can be considered. In addition, a proper number of zero bits (e.g., zero-valued bits) can be added at the very beginning to make it.

The method 1601 then operates by placing RS coded data into matrix, as shown in a block 1631. This may be viewed as arranging the RS coded bits as matrix formatted bits such that the RS coded bits are emplaced in accordance with some pattern (e.g., a predetermined pattern) thereby forming the matrix formatted bits. This operates by placing all RS coded data into a matrix (e.g., by generating matrix formatted bits). In some embodiments, K1×N×Q is a multiple of M (M>1), i.e., K1×N×Q=K2×M, where Q is the Galois field order of RS (2̂Q or 2^{Q}) codes, K2>=1. (If necessary, code shortening techniques or adding fill bits can be adopted to make the equation to be satisfied).

The method 1601 then operates by dividing matrix into M interleaved groups, as shown in a block 1641. This operates by dividing this data matrix into interleaved M groups. Each group consists of K2 columns. Each group can be defined as one simple LDPC code block or one super LDPC code block that consists of multiple internally interleaved LDPC code blocks. As shown in a block 1651, the method 1601 operates by performing LDPC encoding of the M interleaved groups thereby generating LDPC parity bits. The method 1601 continues by arranging LDPC parity bits in interleaved manner (e.g., same as for systematic bits), as shown in a block 1661. In other words, the parity bits for LDPC codes are arranged in a similar (interleaved) way as performed for systematic bits.

Referring again back to FIG. 15, FIG. 15 shows one example, where 4 RS symbols are placed in a row. The field order is 12. In this embodiment, there is a total of 8 interleaved LDPC code blocks.

In a hardware implementation (e.g., an actual communication device), the memory is partitioned into K1 banks or K1×S banks, where S is a divisor of Q. If S=1, one (1) symbol per memory entry can be stored or multiple symbols per entry can be stored as indicated with dotted rectangles in FIG. 15. The number of symbols that can be stored depends on the memory bandwidth requirement.

For LDPC decoding, data is loaded sequentially for each memory bank After decoding, the data is stored back in the same way. After LDPC decoding, RS decoding is performed. The RS symbols are read in a skewed way indicated by the arrows shown in FIG. 15. In this way, memory access conflicts are avoided. Multiplexers (or some appropriate switching scheme) are employed at the output side. The value of K1 should be minimized, if possible.

After RS decoding, the data sequence is output directly.

One special code example is given as follows:

For each ODU sub-frame of 30592 bits, 8 CRC bits are added to make it a total of 30600 bits. 30600=12×2550, i.e., 2550 symbols over the Galois Field: GF(2¹²). After RS encoding, there is a total of 12×2608=31296 bits. 31296×4/8=15648 bits—which is the source frame size of a LDPC code.

The H matrix of the LDPC code will be a size of 2608×18256, and note that 2608=8×326. Sub-matrix can be size of 326, 652, or 163. The over code rate=30592/(18256×2)=0.8379. The redundancy ratio=(1−0.8379)/0.8379=19.34%.

Again, the overall redundancy of such FEC coding may have an overall redundancy being approximately 20% (e.g., at or near 20% within some predetermined tolerance such as 1%, 3%, etc).

In practice, many shorter-length LDPC codes may be used as inner codes to approach the performance bound of RS codes operating in accordance with (concatenated with) LDPC codes. In addition, removing an outer code while allocating all redundancy bits for those interleaved LDPC codes is also an option in some embodiments.

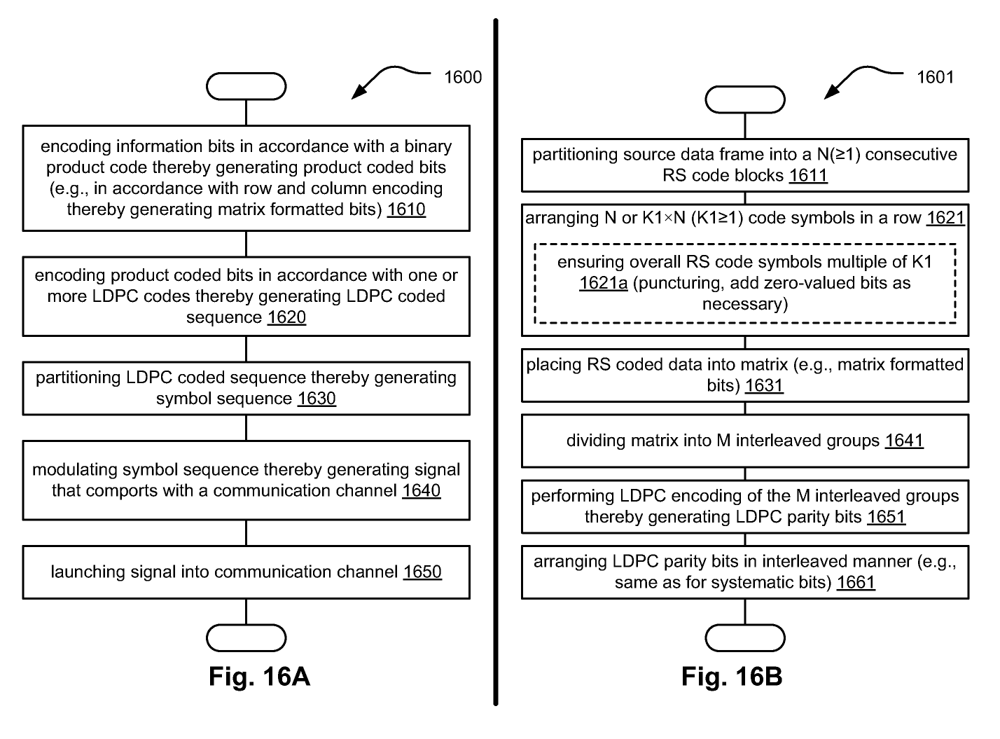

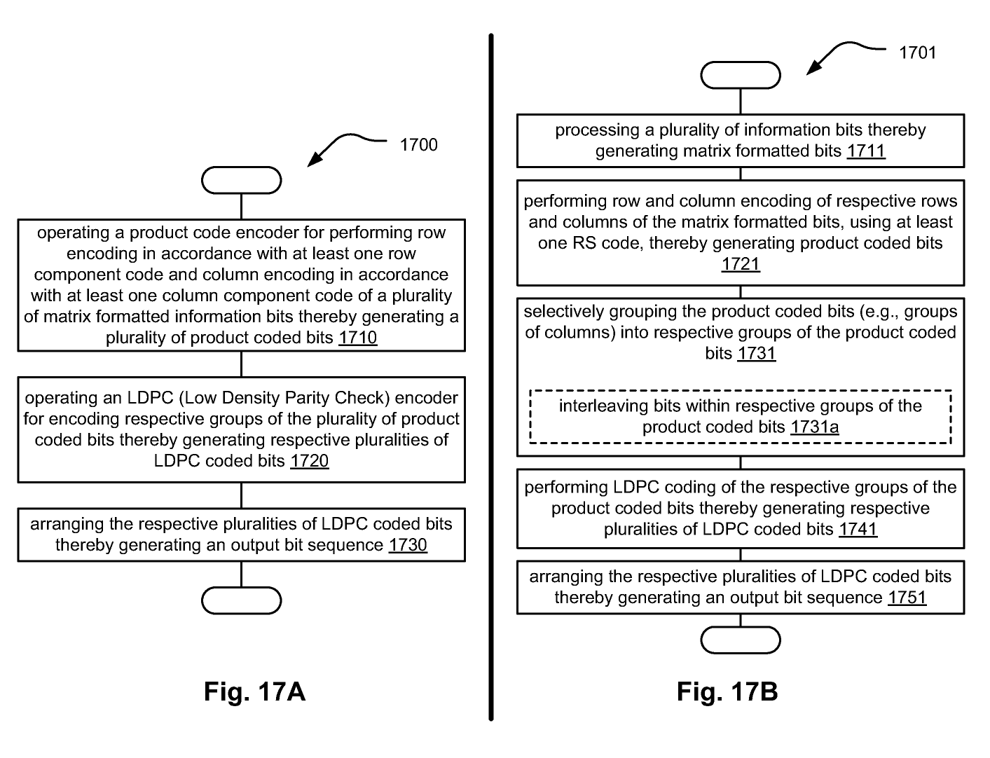

FIG. 17A illustrates an embodiment of method 1700 for performing combined product and LDPC coding. Referring to method 1700 of FIG. 17A, the method 1700 begins by operating a product code encoder for performing row and column encoding of a plurality of matrix formatted bits. The plurality of matrix formatted bits may be viewed as being information bits that have been arranged appropriately into groups (e.g., rows of the matrix formatted bits) and performs encoding thereon. At least one row component code is employed for performing the row encoding on the matrix formatted bits, and at least one column component code is employed for performing the column encoding on the matrix formatted bits thereby generating a plurality of product coded bits, as shown in a block 1710.

The method 1700 continues by operating an LDPC (Low Density Parity Check) encoder for encoding respective groups of the plurality of product coded bits thereby generating respective pluralities of LDPC coded bits, as shown in a block 1720. The method 1700 then operates by arranging the respective pluralities of LDPC coded bits thereby generating an output bit sequence, as shown in a block 1730. As mentioned elsewhere herein, more than one ECC (and more than one LDPC in this particular embodiment) may be employed to perform encoding of the respective different LDPC code groups in certain embodiments.

FIG. 17B illustrates an embodiment of an alternative method 1701 for performing combined product and LDPC coding. Referring to method 1701 of FIG. 17B, the method 1701 begins by processing a plurality of information bits thereby generating matrix formatted bits, as shown in a block 1711. This may be viewed as grouping the plurality of information bits into respective groups (e.g., rows), and the vertical columns of the arranged rows form the ‘columns’ of the matrix formatted bits.

The method 1701 then operates by performing row and column encoding of respective rows and columns of the matrix formatted bits, using at least one RS code, thereby generating product coded bits, as shown in a block 1721. In some embodiments, the same RS code is employed for encoding each of the respective rows and each of the respective columns of the matrix formatted bits. Alternatively, different RS codes may be employed for the respective rows and columns each of the respective rows, and each different RS code may have a different degree of redundancy (such that different numbers of parity bits are generated from each respective row and/or column.

The method 1701 continues by selectively grouping the product coded bits (e.g., groups of columns) into respective groups of the product coded bits, as shown in a block 1731. In some embodiments, interleaving of some of the bits in these respective groups may undergo interleaving, as shown in a block 1731a. The method 1701 then operates by performing LDPC coding of the respective groups of the product coded bits thereby generating respective pluralities of LDPC coded bits, as shown in a block 1741. The method 1701 then operates by arranging the respective pluralities of LDPC coded bits thereby generating an output bit sequence, as shown in a block 1751.

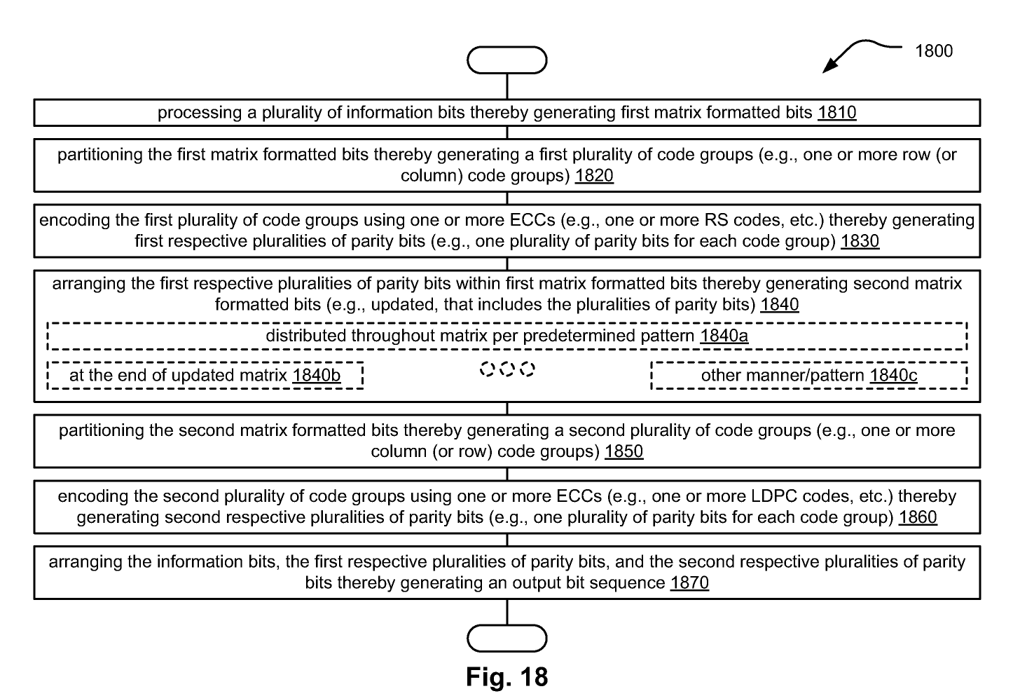

FIG. 18 illustrates an embodiment of a method 1800 for performing concatenated coding both using LDPC (Low Density Parity Check) and Reed-Solomon (RS) coding. Referring to method 1800 of FIG. 18, the method 1800 begins by processing a plurality of information bits thereby generating first matrix formatted bits, as shown in a block 1810. The method 1800 continues by partitioning the first matrix formatted bits thereby generating a first plurality of code groups (e.g., one or more row (or column) code groups), as shown in a block 1820.

The method 1800 then operates by encoding the first plurality of code groups using one or more ECCs (e.g., one or more RS codes, etc.) thereby generating first respective pluralities of parity bits (e.g., one plurality of parity bits for each code group), as shown in a block 1830. The method 1800 continues by arranging the first respective pluralities of parity bits within first matrix formatted bits thereby generating second matrix formatted bits (e.g., updated, that includes the pluralities of parity bits), as shown in a block 1840. The second matrix formatted bits may be viewed as being an updated version of the first matrix formatted bits (e.g., by including the first respective pluralities of parity bits).

In some embodiments, this arranging may be performed by having the first respective pluralities of parity bits distributed throughout matrix per predetermined pattern, as shown in a block 1840a. Alternatively, this arranging may be performed by having the respective pluralities of parity bits situated at the end of updated matrix, as shown in a block 1840b. Generally speaking, this arranging may be performed by having the respective pluralities of parity bits distributed and/or arranged within the matrix in accordance with any desired manner/pattern, as shown generally in a block 1840z.

The method 1800 continues by partitioning the second matrix formatted bits thereby generating a second plurality of code groups (e.g., one or more column (or row) code groups), as shown in a block 1850. The method 1800 then operates by encoding the second plurality of code groups using one or more ECCs (e.g., one or more LDPC codes, etc.) thereby generating second respective pluralities of parity bits (e.g., one plurality of parity bits for each code group), as shown in a block 1860.

The method 1800 continues by arranging the information bits, the first respective pluralities of parity bits, and the second respective pluralities of parity bits thereby generating an output bit sequence, as shown in a block 1870. A subsequent signal corresponding to the output bit sequence is then generated for use in transmitting information via a communication channel (e.g., from a first communication device to a second communication device).

It is noted that the various modules (e.g., encoding modules, decoding modules, interleavers, symbol mappers, etc.) described herein may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The operational instructions may be stored in a memory. The memory may be a single memory device or a plurality of memory devices. Such a memory device may be a read-only memory, random access memory, volatile memory, non-volatile memory, static memory, dynamic memory, flash memory, and/or any device that stores digital information. It is also noted that when the processing module implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry. In such an embodiment, a memory stores, and a processing module coupled thereto executes, operational instructions corresponding to at least some of the steps and/or functions illustrated and/or described herein.

It is also noted that any of the connections or couplings between the various modules, circuits, functional blocks, components, devices, etc. within any of the various diagrams or as described herein may be of any type as desired such as a direct connection, an indirection connection (e.g., with one or more intervening components there between), a communicative coupling, etc. without departing from the scope and spirit of the invention.

Various aspects of the present invention have also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

Various aspects of the present invention have been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, various aspects of the present invention are not limited to such embodiments. It will be obvious to one of average skill in the art that various changes and modifications may be practiced within the spirit and scope of the invention, as limited only by the scope of the appended claims.

What is claimed is:

1. An apparatus, comprising:
a product code encoder for encoding a plurality of information bits, by employing at least one row component code and at least one column component code, thereby generating a plurality of product coded bits;
an LDPC (Low Density Parity Check) encoder for encoding respective groups of the plurality of product coded bits thereby generating respective pluralities of LDPC coded bits; and
a transmit driver, communicatively coupled to the encoder module, for arranging the respective pluralities of LDPC coded bits thereby generating an output bit sequence.

2. The apparatus of claim 1, wherein:
the transmit driver including a modulator for processing the output bit sequence thereby generating a signal being suitable for launching into a communication channel.

3. The apparatus of claim 1, wherein:
the product code encoder employing at least one of a BCH (Bose and Ray-Chaudhuri, and Hocquenghem) code and a Reed-Solomon (RS) code for encoding the plurality of information bits thereby generating the plurality of product coded bits.

4. The apparatus of claim 1, wherein:
the plurality of product coded bits being partitioned into a plurality of product coded bit groups;
the LDPC encoder employing an LDPC code for encoding a first group of the plurality of product coded bit groups thereby generating a first respective plurality of LDPC coded bits; and
the LDPC encoder employing the LDPC code for encoding a second group of the plurality of product coded bit groups thereby generating a second respective plurality of LDPC coded bits.

5. The apparatus of claim 1, further comprising:
a matrix formatting module, communicatively coupled to the product code encoder, for:
partitioning the plurality of information bits into a plurality of information bit groups; and
arranging the plurality of information bit groups in accordance with a predetermined pattern thereby generating a plurality of matrix formatted bits; and wherein:
the product code encoder encoding bits within a first row of the plurality of matrix formatted bits using a first BCH (Bose and Ray-Chaudhuri, and Hocquenghem) code thereby generating a first plurality of parity bits;
the product code encoder encoding bits within a second row of the plurality of matrix formatted bits using the first BCH code thereby generating a second plurality of parity bits;
the product code encoder encoding bits within a first column of the plurality of matrix formatted bits using a second BCH code thereby generating a third plurality of parity bits; and
the product code encoder encoding bits within a second column of the plurality of matrix formatted bits using the second BCH code thereby generating a fourth plurality of parity bits.

6. The apparatus of claim 1, further comprising:
a matrix formatting module, communicatively coupled to the product code encoder, for:
partitioning the plurality of information bits into a plurality of information bit groups; and
arranging the plurality of information bit groups in accordance with a predetermined pattern thereby generating a plurality of matrix formatted bits; and wherein:
the product code encoder encoding bits within a first row of the plurality of matrix formatted bits using a Reed-Solomon (RS) code thereby generating a first plurality of parity bits; and
the product code encoder encoding bits within a second row of the plurality of matrix formatted bits using the RS code thereby generating a second plurality of parity bits;
the product code encoder encoding bits within a first column of the plurality of matrix formatted bits using a second RS code thereby generating a third plurality of parity bits; and
the product code encoder encoding bits within a second column of the plurality of matrix formatted bits using the second RS code thereby generating a fourth plurality of parity bits.

7. The apparatus of claim 1, wherein:
the output bit sequence, including forward error correction (FEC) coding in accordance with a product code and an LDPC code, includes an overall redundancy being approximately 20%.

8. The apparatus of claim 1, wherein:
at least one additional apparatus, communicatively coupled to the apparatus via a communication channel, receiving a signal corresponding to the output bit sequence; and
the at least one additional apparatus performing soft decision decoding based on the signal thereby generating estimates of the plurality of information bits.

9. The apparatus of claim 1, wherein:
the output bit sequence including a plurality of cyclic redundancy check (CRC) bits.

10. The apparatus of claim 1, wherein:
the apparatus being a communication device; and
the communication device being operative within at least one of a satellite communication system, a wireless communication system, a wired communication system, and a fiber-optic communication system.

11. An apparatus, comprising:
a matrix formatting module for partitioning a plurality of information bits into a plurality of information bit groups;
a Reed-Solomon (RS) encoder employing at least one of a row component code and a column component code for encoding the plurality of information bit groups thereby generating respective pluralities of RS coded bits such that each respective plurality of RS coded bits corresponds to one of the plurality of information bit groups, wherein the respective pluralities of RS coded bits are combined with the plurality of information bit groups thereby generating a first plurality of coded bit groups;
an LDPC (Low Density Parity Check) encoder, communicatively coupled to the RS encoder, for encoding the first plurality of coded bit groups thereby generating respective pluralities of LDPC coded bits such that each respective plurality of LDPC coded bits corresponds to one of the plurality of coded bit groups, wherein the respective pluralities of LDPC coded bits are combined with the first plurality of coded bit groups thereby generating a second plurality of coded bit groups; and
a transmit driver, communicatively coupled to the LDPC encoder, for arranging the second plurality of coded bit groups thereby generating an output bit sequence; and wherein:
each of the plurality of product coded bit groups being a respective, interleaved product coded bit group.

12. The apparatus of claim 11, wherein:
the transmit driver including a modulator for processing the output bit sequence thereby generating a signal being suitable for launching into a communication channel.

13. The apparatus of claim 11, wherein:
the output bit sequence, including forward error correction (FEC) coding in accordance with a RS code and an LDPC code, includes an overall redundancy being approximately 20%.

14. The apparatus of claim 11, wherein:
at least one additional apparatus, communicatively coupled to the apparatus via a communication channel, receiving a signal corresponding to the output bit sequence; and
the at least one additional apparatus performing soft decision decoding based on the signal thereby generating estimates of the plurality of information bits.

15. The apparatus of claim 11, wherein:
the plurality of information bit groups including N RS code blocks;
the first plurality of coded bit groups being arranged as a matrix such that each row of the matrix includes N or K1×N code symbols and the first plurality of coded bit groups includes M interleaved coded bit groups;
Q is a Galois field order, 2^{Q}, of an RS code employed by the RS encoder;
N, K1, K2, M, and Q are each respective integers each respectively being greater than or equal to one; and
K1×N×Q=K2×M for the matrix; or
the matrix including at least one fill bit that is a zero-valued bit, a cyclic redundancy check (CRC) bit, or a predetermined bit to ensure that K1×N×Q=K2×M for the matrix.

16. The apparatus of claim 11, wherein:
the apparatus being a communication device; and
the communication device being operative within at least one of a satellite communication system, a wireless communication system, a wired communication system, and a fiber-optic communication system.

17. A method, comprising:
operating a product code encoder for performing row encoding in accordance with at least one row component code and column encoding in accordance with at least one column component code of a plurality of matrix formatted information bits thereby generating a plurality of product coded bits;
operating an LDPC (Low Density Parity Check) encoder for encoding respective groups of the plurality of product coded bits thereby generating respective pluralities of LDPC coded bits; and
arranging the respective pluralities of LDPC coded bits thereby generating an output bit sequence.

18. The method of claim 17, wherein:
the product code encoder employing at least one of a BCH (Bose and Ray-Chaudhuri, and Hocquenghem) code and a Reed-Solomon (RS) code for encoding the plurality of information bits thereby generating the plurality of product coded bits.

19. The method of claim 17, further comprising:
including a plurality of cyclic redundancy check (CRC) bits within the output bit sequence.

20. The method of claim 17, wherein:
the method being performed within a communication device; and
the communication device being operative within at least one of a satellite communication system, a wireless communication system, a wired communication system, and a fiber-optic communication system.
